(19) United States
(12) Patent Application Publication
(10) Pub. No.: US 2014/0291711 A1
(43) Pub. Date: Oct. 2, 2014

(54) SEMICONDUCTOR LIGHT EMITTING DEVICE AND PACKAGE STRUCTURE THEREOF

(71) Applicant: Lextar Electronics Corporation, Hsinchu (TW)

(72) Inventor: Tzu-Lung Lee, Miaoli City (TW)

(73) Assignee: Lextar Electronics Corporation, Hsinchu (TW)

(21) Appl. No.: 14/054,946

(22) Filed: Oct. 16, 2013

(30) Foreign Application Priority Data
Mar. 29, 2013 (TW) 102111506

(51) Int. Cl. H01L 33/58

(52) U.S. Cl. CPC H01L 33/58
USPC 257/98

(57) ABSTRACT

A semiconductor light emitting device and a package structure thereof are provided. The semiconductor light emitting device includes a substrate, an epitaxial structure layer, a first electrode, a second electrode and a patterned film structure. The substrate has a first surface and a second surface opposite to the first surface. The epitaxial structure layer is disposed on the first surface, and includes a first type semiconductor layer, an active layer and a second type semiconductor layer on the first surface in sequence. The first electrode is formed on an exposed surface of the first type semiconductor layer. The second electrode is formed on an exposed surface of the second type semiconductor layer. The patterned film structure is disposed on the second surface and includes thin films composed of a metamaterial having a negative refraction index.

This application claims the benefit of Taiwan application Serial No. 102111506, filed Mar. 29, 2013, the subject matter of which is incorporated herein by reference.

### BACKGROUND OF THE INVENTION

1. Field of the Invention

The invention relates in general to a semiconductor light emitting device, and more particularly to a semiconductor light emitting device have a negative refraction index and a package structure thereof.

2. Description of the Related Art

In the field of semiconductor light emitting device, the lens is often used to change the direction of the light. Since the lens is normally formed by a material having positive dielectric constant and positive magnetic permeability, the light being refracted by the lens will deviate from the normal line according to the law of refraction. The incident light and the refracted light are on two different sides of the normal line. Different mediums have different refraction indexes. The refraction index of the air is defined as 1, and the refraction indexes of other mediums are relative to the refraction index of the air. The speed of the light is fastest when travelling in the vacuum atmosphere. The refraction indexes of other mediums are larger than that of the air. For instance, the refraction indexes of water, glass and sapphire substrate are 1.33, 1.5, and 1.77 respectively.

A medium having a negative dielectric constant and a negative magnetic permeability (that is, a double-negative material) is referred as a left-handed material whose properties are different from the right-hand rule in electromagnetism. The electromagnetic behavior of a left-handed material is completely different from that of an ordinary material. For instance, the direction of the light is opposite to the direction of energy propagation, hence generating a negative refraction index.

Referring to FIGS. 1A and 1B, schematic diagrams illustrating the refraction occurring when the light passes through a medium are respectively shown. As indicated in FIG. 1A, when the medium 1 and the medium 2 both have a positive refraction index, the incident light 10 and the refracted light 12 are located on two different sides of the normal line N. Meanwhile, the refraction angle θ1 is a positive value. As indicated in FIG. 1B, when the medium 1 has a positive refraction index but the medium 2 has a negative refraction index, the incident light 10 and the refracted light 12 are located on the same side of the normal line N. Meanwhile, the refraction angle θ2 is a negative value. Therefore, how to use the properties of negative refraction index or the structure having a negative refraction index to enhance the concentrating effect of the light source emitted has become a focus of development for the industries.

### SUMMARY OF THE INVENTION

The invention is directed to a semiconductor light emitting device and a package structure thereof having a negative refraction index capable of refracting and further converging the light to increase the vertical intensity of light source per unit area.

According to one embodiment of the present invention, a semiconductor light emitting device including a substrate, an epitaxial structure layer, a first electrode, a second electrode and a patterned film structure is provided. The substrate has a first surface and a second surface opposite to the first surface. The epitaxial structure layer is disposed on the first surface, and includes a first type semiconductor layer, an active layer and a second type semiconductor layer on the first surface in sequence. The first electrode is formed on an exposed surface of the first type semiconductor layer. The second electrode is formed on an exposed surface of the second type semiconductor layer. The patterned film structure is disposed on the second surface, and includes thin films composed of a meta material having a negative refraction index.

According to another embodiment of the present invention, a package structure of a semiconductor light emitting device is provided. The package structure includes a package, a cover and a patterned film structure. The package supports a light emitting device. The cover covers the package and the light emitting device, and has a first surface and a second surface opposite to the first surface. The patterned film structure is disposed on the first surface or the second surface, and includes thin films composed of a metamaterial having a negative refraction index.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A and 1B are schematic diagrams illustrating the refraction occurring when the light passes through a medium;

FIGS. 2A and 2B respectively are schematic diagrams of a patterned film structure being a sub-wavelength hole array structure or a sub-wavelength mesh structure;

FIG. 3 is a schematic diagram of a semiconductor light emitting device according to an embodiment of the present invention;

FIG. 4 is a schematic diagram of a multi-thin-film structure in which the metamaterial is formed by alternately stacking a plurality of first thin films and a plurality of second thin films;

FIG. 5 is a diagram illustrating the relationship between the number of layers of first thin films and the negative refraction index of the metamaterial;

FIGS. 6A and 6B are schematic diagrams of forming a multi-layer gradient thin-film structure by using the metamaterial;

FIG. 7 is a schematic diagram of a package structure of a semiconductor light emitting device according to an embodiment of the present invention.

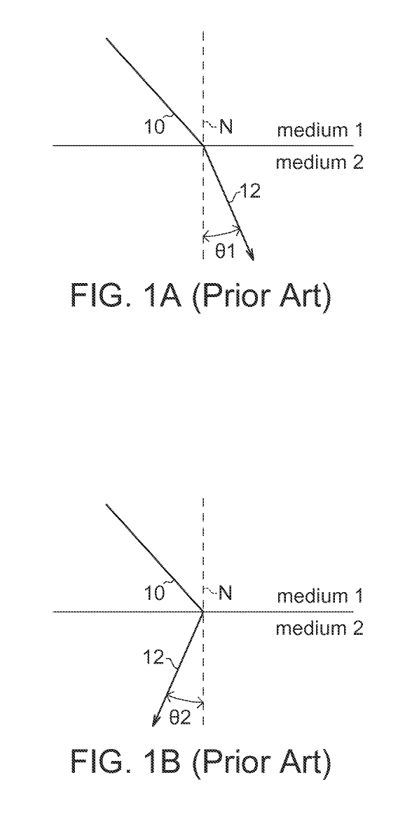

### DETAILED DESCRIPTION OF THE INVENTION

A semiconductor light emitting device and a package structure thereof are disclosed in the present embodiment. The patterned film structure is formed by a metamaterial having a negative refraction index. The patterned film structure may be a multi-thin-film structure formed by alternately stacking a metallic material and a non-metal material according to a periodic arrangement of thin films. The thin films are further etched to form a patterned film. Broadly speaking, the metamaterial may refer to any synthetic materials, but normally refer to a material having a negative refraction index. All the known materials in the natural world have positive refraction indexes, and the natural world does not have any materials having negative refraction indexes. In the present embodiment, a nanometer structure with man-made sub-wavelength is etched, such that the propagation of the light can be controlled and a material having a negative refraction index can thus be obtained.

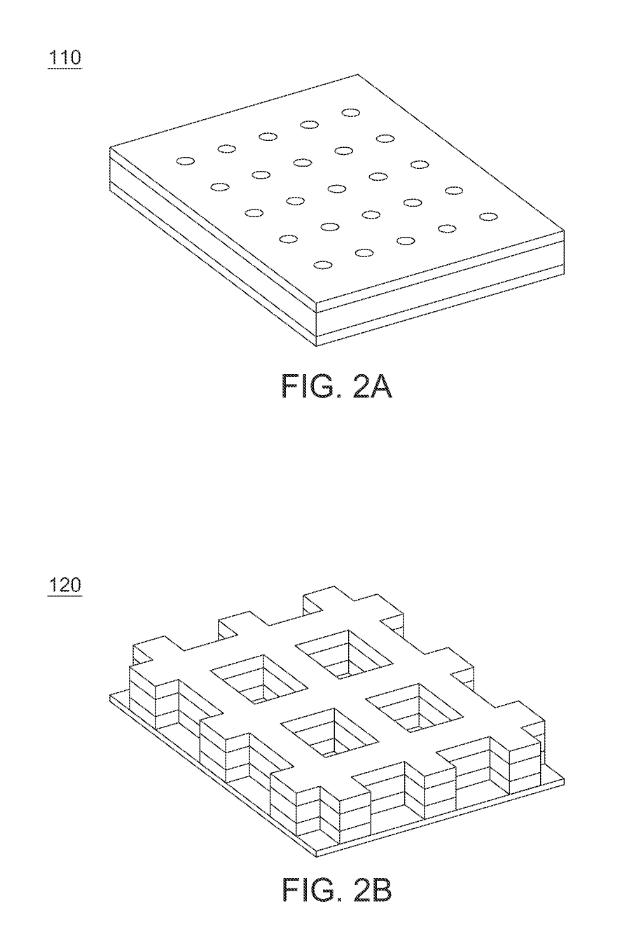

Referring to FIGS. 2A and 2B, schematic diagrams of a patterned film structure being a sub-wavelength hole array structure 110 or a sub-wavelength mesh structure 120 are respectively shown. The present embodiment achieves gradient change in optical refraction index through the design of gradient structure. The scale of the structure with gradient change is normally smaller than or approximately equal to a wavelength, and such structure is also referred as a sub-wavelength structure (SWS).

The SWS, being smaller than a wavelength, does not generate interference or diffraction on the incident light but will change the refraction index due to the difference in the densities of the mediums in the space. The gradient change in refraction index reduces the reflection of the incident light which occurs due to the difference in refraction index. The sub-wavelength nanometer structure manufactured under the nano-scale can obtain full-band antireflection effect and produce a very low reflectivity even when the light enters the sub-wavelength nanometer structure at a large incident angle. The above mechanism of changing refraction index through the structural change can be understood from a microcosmic point of view. Since the patterned film structure is formed by stacking multi-layer gradient thin films, the differences in refraction indexes between layers of thin films are very close to each other. It can be known from the equation of optical transmittance on material interface that the transmittance of the patterned film structure is close to 1.

A number of embodiments are disclosed below for elaborating the Invention. However, the embodiments of the invention are for detailed descriptions only, not for limiting the scope of protection of the invention.

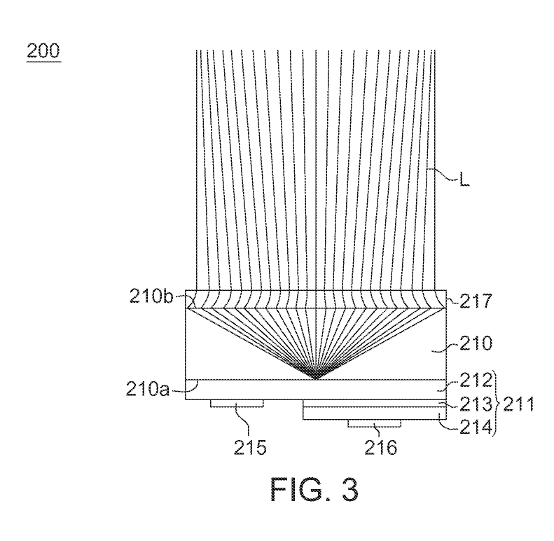

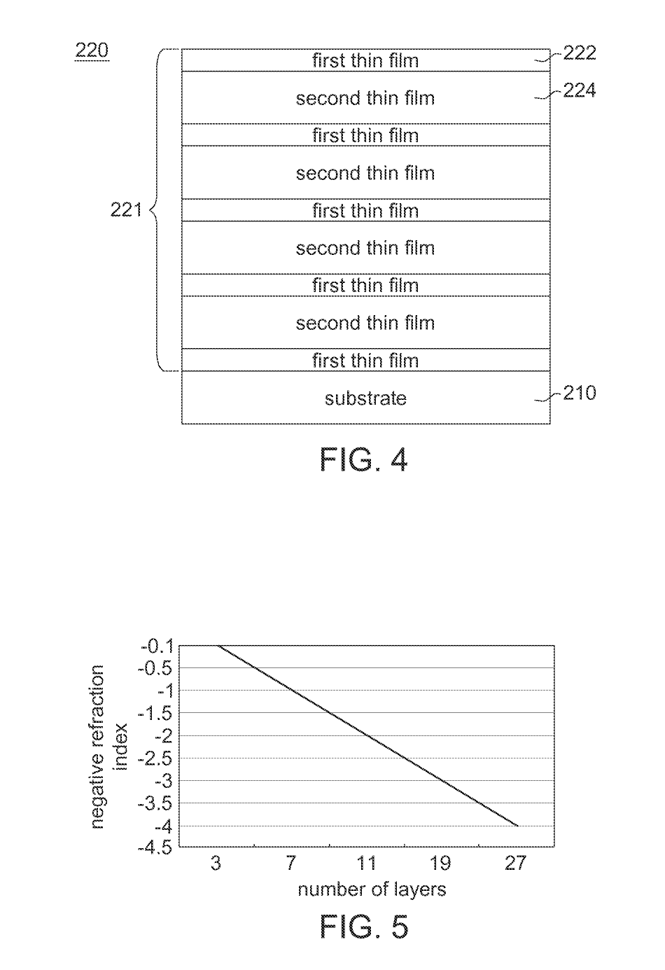

Referring to FIG. 3, a schematic diagram of a semiconductor light emitting device 200 according to an embodiment of the present invention is shown. The semiconductor light emitting device 200 includes a substrate 210, an epitaxial structure layer 211, a first electrode 215, a second electrode 216 and a patterned film structure 217. The substrate 210 has a first surface 210a and a second surface 210b opposite to the first surface 210a. The epitaxial structure layer 211 is disposed on the first surface 210a, and includes a first type semiconductor layer 212, an active layer 213 and a second type semiconductor layer 214 on the first surface 210a in sequence. The first electrode 215 is formed on an exposed surface of the first type semiconductor layer 212. The second electrode 216 is formed on an exposed surface of the second type semiconductor layer 214. The patterned film structure 217 is disposed on the second surface 210b, and includes thin films composed of a metamaterial 221 having a negative refraction index as indicated in FIG. 4.

The substrate 210 can be a sapphire substrate, a silicon carbide substrate or a silicon substrate. The epitaxial structure layer 211 may be formed by a nitride composed of group ETA elements. The first type semiconductor layer 212 can be an N type semiconductor layer, and the second type semiconductor layer 214 can be a P type semiconductor layer. Or, the first type semiconductor layer 212 can be a P type semiconductor layer, and the second type semiconductor layer 214 can be an N type semiconductor layer. When a voltage is applied to two ends of the first electrode 215 and the second electrode 216, electrons will he combined with holes in the active layer 213. After electrons and holes are combined, the energy will be emitted in the form of a light.

Referring to FIG. 4, a schematic diagram of a multi-thin-film structure 220 in which the metamaterial 221 is formed by alternately stacking a plurality of first thin films 222 and a plurality of second thin films 224. The first thin films 222 are formed by a metallic material, for example. Preferably but not restrictively, the first thin films 222 are a nanometer column structure having a negative refraction index, and may contain gold or silver such as nanometer silver. The second thin films 224 can be formed by a non-metallic medium having a positive refraction index. The non-metallic medium can be formed by a material such as resin, nitride (such as silicon nitride), oxide (such as silicon dioxide) or nitrogen oxide.

The refraction index of the metamaterial 221 can be changed through the design of structural change. For instance, as the number of layers of the first thin films 222 increases, the negative refraction index of the metamaterial 221 decreases accordingly (such as from −0.1 to −4.0). Conversely, as the number of layers decreases, the negative refraction index of the metamaterial 221 will increases accordingly (such as from −4.0 to −0.1). Referring to FIG. 5, a diagram illustrating the relationship between the number of layers of the first thin films 222 and the negative refraction index of the metamaterial 221 is shown. The first thin films 222 have 3 to 27 layers for example, and the refraction index of the metamaterial 221 is between −0.1 to −4.0 accordingly.

As indicated in FIG. 4, when the light enters the patterned film structure 217 having a negative refraction index from the substrate 210 having a positive refraction index, the incident light and the refracted light are on the same side of the normal line of the interface, and such refraction is opposite to ordinary refraction. Therefore, the patterned film structure 217 having a negative refraction index can be used to enhance the concentrating effect of the light source, such that the light L converges inwardly and the vertical intensity of the light source through the substrate per unit area increases.

In the present embodiment, when the number of layers of the first thin films 222 progressively increases from the center of the substrate 210 in a stepped manner, the refraction index of the patterned film structure 217 changes due to the difference in the densities of mediums in the space, such that the negative refraction index of the metamaterial 221 progressively decreases outwardly from the center of the substrate 210 in a stepped manner.

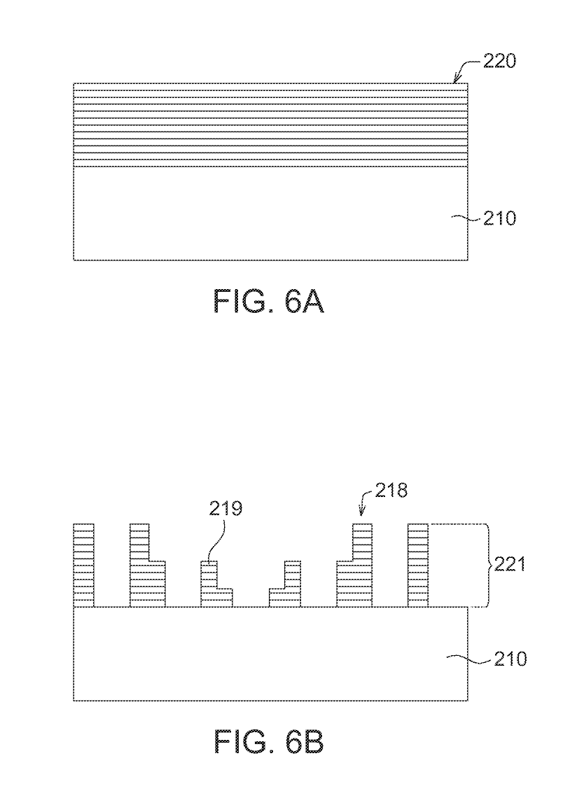

Referring to FIGS. 6A and 6B, schematic diagrams of forming a multi-layer gradient thin-film structure by using metamaterial 221 are respectively shown. As indicated in FIG. 6A, the multi-thin-film structure 220 is formed by alternately stacking the first thin films 222 having negative refraction indexes and the second thin films 224 having positive refraction indexes by using the chemical deposition process or the physical deposition process. Next, as indicated in FIG. 6B, the multi-thin-film structure 220 is etched by the mask process to form a multi-layer gradient thin-film structure 218. The multi-layer gradient thin-film structure 218 has the properties of the sub-wavelength hole array structure 110 or the sub-wavelength mesh structure 120 disclosed above. Furthermore, the number of layers of the thin films 219 progressively increases from the center of the substrate 210 in a stepped manner, such that the refraction index of the metamaterial 221 progressively decreases outwardly from the center of the substrate 210 in a stepped manner.

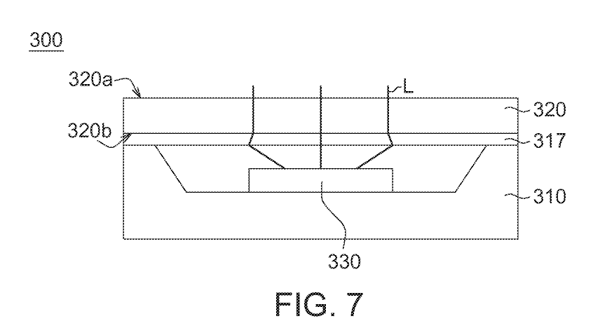

Referring to FIG. 7, a schematic diagram of a package structure 300 of a semiconductor light emitting device according to an embodiment of the present invention is shown. The package structure 300 of a semiconductor light emitting device includes a package 310 and a cover 320. The package 310 supports a light emitting device 330. The cover 320 covers the package 310 and the light emitting device 330. The cover 320 has a first surface 320a and a second surface 320b opposite to the first surface 320a. A patterned film structure 317 is formed on the first surface 320a or the second surface 320b of the cover 320, and includes thin films composed of a metamaterial having a negative refraction index.

When the light enters the patterned film structure 317 having a negative refraction index from the medium (such as the air or glass) having a positive refraction index , the incident light and the refracted light are on the same side of the normal line of the interface, and such refraction is opposite to ordinary refraction. Therefore, the patterned film structure 317 having a negative refraction index can be used to enhance the concentrating effect of the light source, such that the light L converges inwardly and the vertical intensity of the light source per unit area increases.

The thin-film structure 218, having multi-layers and gradient change, is composed of the metamaterial 221. The number of layers of the thin films 219 progressively increases outwardly from the center of the cover 320 in a stepped manner, such that the negative refraction index of the metamaterial 221 progressively decreases outwardly from the center of the cover 320 in a stepped manner.

The semiconductor light emitting device and the package structure thereof disclosed in above embodiments have a negative refraction index capable of refracting and converging the light to increase the vertical intensity of the light source per unit area. Therefore, the semiconductor light emitting device and the package structure of the present invention can replace large-sized lens, not only reducing the thickness of the product but also saving the assembly cost of lens.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should he accorded the broadest interpretation so as to encompass all such modifications and similar arrangements and procedures.

What is claimed is:

1. A semiconductor light emitting device, comprising:
a substrate having a first surface and a second surface opposite to the first surface;
an epitaxial structure layer disposed on the first surface, wherein the epitaxial structure layer comprises a first type semiconductor layer, an active layer and a second type semiconductor layer on the first surface in sequence;
a first electrode formed on an exposed surface of the first type semiconductor layer;
a second electrode formed on an exposed surface of the second type semiconductor layer; and
a patterned film structure disposed on the second surface, wherein the patterned film structure comprises thin films composed of a metamaterial having a negative refraction index.

2. The semiconductor light emitting device according to claim 1, wherein the patterned film structure is formed by alternately stacking a plurality of first thin films and a plurality of second thin films, the first thin films have negative refraction indexes, and the second thin films have positive refraction indexes.

3. The semiconductor light emitting device according to cairn 2, wherein a number of layers of the first thin films progressively increase outwardly from a center of the substrate in a stepped manner, such that the refraction index of the metamaterial progressively decreases outwardly from the center of the substrate in a stepped manner.

4. The semiconductor light emitting device according to claim 3, wherein the number of layers of the first thin films progressively increase outwardly from the center of the substrate in a stepped manner.

5. The semiconductor light emitting device according to claim 1, wherein the patterned film structure is a sub-wavelength hole array structure.

6. The semiconductor light emitting device according to claim 1, wherein the patterned film structure is a sub-wavelength mesh structure.

7. The semiconductor light emitting device according to claim 2, wherein the first thin films is composed of the metamaterial comprising a nanometer column structure.

8. The semiconductor light emitting device according to claim 7, wherein the nanometer column structure contains gold or silver.

9. The semiconductor light emitting device according to claim 2, wherein the first thin films have 3 to 27 layers.

10. The semiconductor light emitting device according to claim 1, wherein the refraction index of the metamaterial is between −0.1 to −4.0.

11. A semiconductor light emitting device the package structure, comprising:
a package supporting a light emitting device;
a cover covering the package and the light emitting device, wherein the cover has a first surface and a second surface opposite to the first surface; and
a patterned film structure disposed on the first surface or the second surface, wherein the patterned film structure comprises thin films composed of a metamaterial having a negative refraction index.
